(19) United States
(12) Patent Application Publication
(10) Pub. No.: US 2004/0051030 A1
(43) Pub. Date: Mar. 18, 2004

(54) Method and apparatus for acquiring images from a multiple axis imaging system

(76) Inventors: Artur Olszak, Tucson, AZ (US); James Goodall, Tucson, AZ (US); Ibrahim Bardak, Tucson, AZ (US)

Correspondence Address: William A. Birdwell, Durando Birdwell & Janke, P.L.C., 2929 E. Broadway Blvd., Tucson, AZ, 85716, US

(21) Appl. No.: 10/245,740

(22) Filed: Sep. 17, 2002

(51) Int. Cl. H01L 27/00

(52) U.S. Cl. 250/208.1

(57) ABSTRACT

A method and apparatus for acquiring images from a multiple axis imaging system. A data processing device is provided for receiving image data as it is read out of an imaging array, reorganizing the data, and otherwise processing it, for storage or in memory or transmission for display. The imaging system scans an object with an array of imaging elements having corresponding detectors for capturing the images. The data processing device reorganizes the data so that the data order corresponds to spatial locations of the respective object regions. The data may be transmitted in correct order for display of an image of the entire object, or may be mapped to a memory for rapid access and display of the image. Image processing may also take place prior to transmission or storage of the data. Data processing may be divided among a number of different processors. The data processor may be compressed for transmission.

This invention relates generally to multiple axis imaging systems. More specifically, the invention relates to a method and apparatus for acquiring images from an array of optical imaging elements and corresponding detectors, particularly a miniature microscope array comprising a plurality of magnifying optical imaging elements and corresponding detectors arranged in a two-dimensional array.

### BACKGROUND OF THE INVENTION

Light microscopes are commonly used in biological and biochemical analysis. Such microscopes produce an image of an object corresponding to the field of view of the microscope's imaging lens system. The image may be captured by a detector and stored in a computer for further analysis.

A recent innovation in such imaging is the miniature microscope array (“MMA”). In such an array, a plurality of miniature imaging elements having respective optical axes and magnifications whose absolute value is greater than one are arranged in a two-dimensional array for producing respective enlarged images of respective objects or portions of a single object. For imaging a single object or specimen, the plurality of imaging elements together function in the manner of a single microscope by forming respective partial images of the object that are subsequently concatenated to form a whole image (hereinafter “array microscope”). Alternatively, the individual imaging elements may be used to wholly image, respectively, corresponding disparate objects or specimens supported by a common slide or carriage to function as an array of microscopes (hereinafter “microscope array”).

In an MMA, the array of the imaging elements (hereinafter “imaging array”) are ordered in rows and columns, the rows of elements extending in a first dimension across an object while the object is translated in a second dimension past the fields of view of the individual imaging elements in the array, to create respective column strips of data corresponding to each miniature imaging element. These data are acquired so as to produce an image of the object or objects viewed by the MMA. In an MMA, the image size is larger than the lateral field of view of the imaging elements. In addition, the imaging elements are ordinarily diametrically larger than the lateral field of view. Both of these characteristics, alone or together, create a requirement for the MMA that is not readily apparent. That is, the images produced by adjacent imaging elements in the array cannot correspond to contiguous objects or regions of an object. For example, if the diameters of the imaging elements are larger than their fields of view by a factor of ten, or the magnification of the imaging elements is one-to-ten, and if there are two imaging elements forming a first row of the imaging array packed tightly together, the two imaging elements can image only two regions across the object that are only one-tenth the lateral extent of the object and are widely separated from one another.

Looking at the lateral fields of view of the imaging elements as dividing the object into segments, because the diameters of the imaging elements are larger than the segments by a factor of ten, it is only possible to image every tenth segment across the object with the first row of the imaging array. For example, the first row of the imaging array can be used to image the first and the eleventh segments of the first row across the object, or the second and the twelfth segments of the first row across the object, and so on. However, it is not possible to image the first and, for example, the ninth segments of the first row across the object with a single row of the imaging elements because the imaging elements are too large to pack closely enough together.

Thus, assuming the first row of the MMA is provided to image the first and eleventh segments of a given row across the object, a second row of the MMA must be provided to image the second and twelfth segments of the first row across the object, and the object is thereafter moved to align the first row across the object with this second row of the MMA after the first and eleventh segments have been scanned. Similarly, the object is thereafter moved to align the first row across the object with a third row of the MMA which is provided to image the third and thirteenth segments of the first row across the object, and so on, until all twenty segments of the first row across the object are imaged. Therefore, in this explanatory example, imaging one row across the object requires a two-dimensional imaging array comprising ten rows of two imaging elements each in the MMA. In practice, an imaging array that can image the entire area of a standard 20 mm by 50 mm microscopy slide has about 80 imaging elements arranged, for example, in ten rows of eight imaging elements.

It can be seen that when an object is scanned by an MMA, the time frames during which data are acquired from spatially contiguous regions of the object are not temporally contiguous. This often requires reorganization or recording of the data produced by the detectors of the imaging elements to create an image of the object. In the specific case of an array microscope, data acquired from the imaging elements during a particular time frame must be reorganized and stitched together so that data from contiguous regions of the object can be displayed contiguously.

In addition to the afore-described data organization problem that is inherent to an imaging array where the spacing between imaging elements exceeds the fields of view thereof, a similar problem is caused by the detector technology that is suitable for capturing images produced by the imaging elements. Ordinarily, a linear array of detecting elements arranged in the row direction of the array is associated with each imaging element to capture the image produced thereby in one, row dimension. In this case, as the object is advanced with respect to the array during scanning, one-dimensional images are captured by each row during sequential time frames and later read out one pixel at a time in the column direction of the imaging array. Current technology such as CMOS detector arrays allow parallel readout of each line but, as a practical matter, the pixel data in the array is transmitted and processed serially either in the row or column direction, one row or column at a time. Consequently, data from non-contiguous pixels, or sets of pixels, are interlaced with one another. Moreover, this is so even if two-dimensional arrays of detecting elements are associated with each imaging element so that each time frame represents multiple pixels in the column direction of the imaging array.

Thus, while an MMA inherently provides the outstanding advantage of greatly decreasing the time required for acquiring an image due to the parallel processing performed by the plurality of imaging elements in the array, it may be appreciated that to reconstruct the image requires a substantial amount of buffering, reorganization and, typically, stitching of data. In addition, it is often desirable to process the data further, for example, to correct the gain and offset of the data, and to sharpen the image.

Several patents address stitching together data from a plurality of linear detector arrays arranged laterally with respect to an object to produce data representing one row or line across the object in an optical scanner. The fundamental problem addressed is to account for errors in mechanical alignment of the linear arrays. U.S. Pat. No. 4,149,090 and U.S. Pat. No. 4,734,787 address this problem by arranging alternate linear arrays so that they are offset in the scan direction and overlap one another, so that two time frames of scanning are needed to create a full-width row of scan data. The overlapping pixel data are then operated on to stitch together one line, thereby aligning the data laterally. Similarly, U.S. Pat. No. 4,734,787 proposes to stitch data from a plurality of linear detector arrays and associated imaging optics that have laterally overlapping fields of view, and to delay data acquired during earlier time frames corresponding to a line so as to compensate for misalignment in the scan direction. However, there is no recognition in any of these references of the data reorganization problem that is inherent in an ordered array scanner that has either a high numerical aperture or a magnification whose absolute value is greater than one. Nor is there recognition of the problem of creating an image from a stream of interlaced data from non-contiguous object regions.

To capture and process image data from a camera, one known method is to couple the camera via a data-link to a data acquisition circuit which stores the data onto hard disk drives as it streams from the camera. Bacus et al., U.S. Pat. Nos. 6,101,265, 6,226,392, and 6,272,235 provide examples of this method applied to a single-axis microscope. A host computer, such as a personal computer, is connected via an interface bus to the data acquisition circuit, and retrieves the data after it is stored for further manipulation and processing to permit viewing.

In addition to the failure of this strategy to take advantage of the inherently superior data throughput provided by an MMA, the time required to store the data on the hard drive and retrieve the data for reorganization and image processing is highly undesirable, especially in applications such as telepathology, where the time between image acquisition and display should be as close to immediate as possible. For example, about 20-25 minutes may be required to obtain and process a complete high resolution image of a standard 20 mm by 50 mm microscopy slide.

The very large amount of data produced by an MMA only exacerbates this temporal problem. Moreover, since the MMA architecture inherently provides for fast acquisition of data, it is particularly undesirable to burden the MMA with the overhead associated with intermediately storing image data on hard drives before completing the processing necessary for viewing the image. In that regard, in the MMA the time required to reorganize and otherwise process the data for viewing, including, for example, correcting the data for differences in sensor offset and gain, is about five times that required to obtain the data from the sensors. Accordingly, to save time when imaging with MMA's, much larger memory and other computer resources need to be allocated using the standard method for transmitting images.

Accordingly, there is an unfilled need for a method and apparatus for acquiring images from a multiple-axis imaging system such as an MMA that permits reorganizing and processing image data for storage or transmission to a display device in a form suitable for display as fast as the data is acquired.

### SUMMARY OF THE INVENTION

The present invention meets the challenge of providing a method and apparatus for acquiring images from a multiple-axis imaging system, particularly an MMA, by providing a data processing device for receiving image data as it is read out of an imaging array, reordering or reorganizing the data, and otherwise processing it, for storage in memory or transmission for display. The imaging system scans an object with an array of imaging elements having corresponding detectors for capturing the images produced thereby. Temporally contiguous data acquired from the array necessarily corresponds to non-contiguous regions of the object being scanned. According to a reorganization aspect of the invention, the data processor reorganizes or reorders the data so that the data order corresponds to spatial locations of the respective object regions. Thus, the data may be transmitted in correct order for display of an image of the entire object, or may be mapped to a memory for rapid access and display of the image. Image processing may also take place prior to transmission or storage of the data.

According to a data compression aspect of the invention, the data processor compresses all or selected portions of the data to increase the speed of transmission of the data. Preferably, 8×8 pixel “tiles” of the data are aligned according to the aforementioned reorganization aspect and compressed for transmission to or storage in a host computer. The host computer simply aligns the tiles rather than each pixel in the tiles, decreasing substantially the computer's workload. This can be done before or after the decompression required for viewing the image.

According to another aspect of the invention, processing may be divided among a number of different processors, including a number of parallel processors, a pre-processor, a post-processor, and a personal computer (“PC”). The reorganization memory mapping, and compression aspects of the invention may be employed together or separately, and may be employed with any number of processors to proportion the total work load in order to achieve higher processing speed, lower cost, or both.

Accordingly, it is a principal object of the present invention to provide a novel method and apparatus for acquiring images from a multiple-axis imaging system.

It is another object of the present invention to provide a novel method and apparatus for acquiring images from an MMA.

It is a further object of the present invention to provide a novel method and apparatus for acquiring images from an array microscope.

It is yet another object of the present invention to provide a novel method and apparatus for reducing the time required for displaying an image captured by a multiple-axis imaging system.

It is yet a further object of the present invention to reduce the required storage capacity for an image produced by a multiple-axis imaging system.

It is another object of the present invention to provide a novel method and apparatus for reducing the time required to transmit an image produced by a multiple-axis imaging system from one location to another.

The foregoing and other objectives, features and advantages of the invention will be more readily understood upon consideration of the following detailed description of the invention, taken in conjunction with the accompanying drawings.

### BRIEF DESCRIPTION OF THE DRAWINGS

FIG. 1 is a pictorial view of a miniature microscope array (“MMA”).

FIG. 2 is a schematic diagram illustrating principles of imaging an object with a portion of the imaging array of an MMA, showing the object in a first relative position with respect to the imaging array.

FIG. 3 is a schematic diagram of the object and a portion of the imaging array shown in FIG. 2 along with another portion of the imaging array, showing the object in a second relative position with respect to the array.

FIG. 4 is a schematic diagram of the object and portion of the imaging array shown in FIG. 3 along with yet another portion of the imaging array, showing the object in a third relative position with respect to the array.

FIG. 5A is a schematic diagram of the imaging array of FIG. 4 and another object for imaging with the imaging array.

FIG. 5B is a schematic diagram of one of the imaging elements of FIG. 4, shown with a linear detector array.

FIG. 6A is a schematic diagram of the imaging array of FIG. 5 shown with pixel detecting elements.

FIG. 6B is a data stream output from the imaging array of FIG. 6A according to a memory mapping aspect of the present invention.

FIG. 6C is a schematic diagram of an object scanned by the imaging array of FIG. 6A, showing physical locations on the object corresponding to the data in the data stream of FIG. 6B.

FIG. 6D is a schematic diagram of a memory for mapping the data of FIG. 6B according to the physical locations of FIG. 6C.

FIG. 6E is a schematic diagram showing a memory mapping of the data of FIG. 6B to the memory of FIG. 6D.

FIG. 7A is an exemplary matrix of image data organized according to the principles of the present invention.

FIG. 7B is an output stream of the data of FIG. 7A.

FIG. 8A is an exemplary memory map for storing the data of FIG. 7A according to the present invention.

FIG. 8B is an output stream of the data accessed from the memory of FIG. 8A.

FIG. 9 is an exemplary method for transmitting images from an MMA according to an aligning aspect of the present invention.

FIG. 10 is a block diagram of a hardware system for transmitting images from an MMA according to the present invention, comprising an external DSP unit and associated RAM for use with a host computer.

FIG. 11 is a block diagram of an alternative hardware system for transmitting images from an MMA according to the present invention, wherein the DSP unit and RAM of FIG. 6 is onboard the host computer.

FIG. 12 is a block diagram of yet another alternative hardware system for transmitting images from an MMA according to the present invention, wherein the DSP and RAM of FIG. 6 comprises a plurality of parallel portions for parallel processing.

FIG. 13 is a block diagram of still another alternative hardware system for transmitting images from an MMA according to the present invention, including an FPGA processor and a data compression chip.

FIG. 14 is a block diagram of a further alternative hardware system for transmitting images from an MMA according to the present invention, including a pre-processor and a post-processor.

### DETAILED DESCRIPTION OF PREFERRED EMBODIMENTS

The present invention relates generally to multiple axis imaging systems.

The Basic MMA

A recent development in the area of multiple axis imaging systems is the MMA, which is particularly useful to pathologists, who need to quickly scan and image entire tissue or fluid samples in order to find and scrutinize pathologies that may be present in only a very small portion of the sample. For this purpose, individual imaging elements of MMAs are closely packed and have a high numerical aperture. This enables the capture of high-resolution microscopic images of the entire sample in a short period of time by scanning the specimen with the array. The present invention particularly provides for decreasing this time. While described in the context of an MMA, and particularly an MMA used to image a plurality of regions of one object and referred to herein as an array microscope, the invention may be used in any multiple axis imaging system in which its features and benefits may be desired.

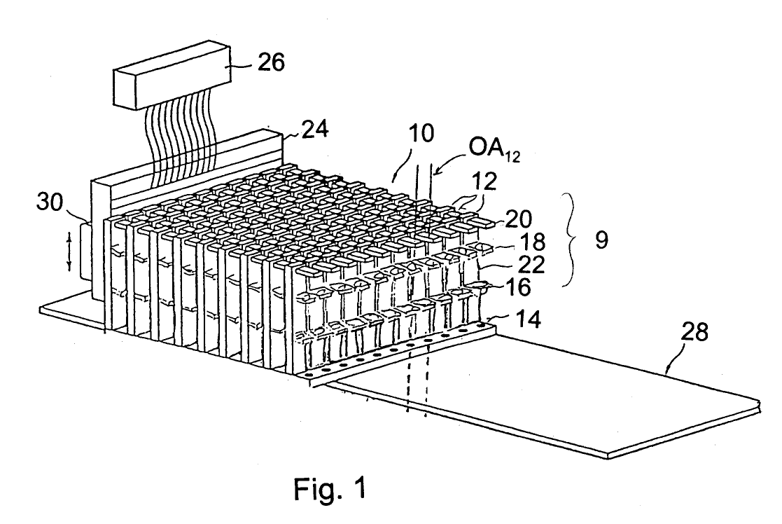

An exemplary MMA 10 is shown in FIG. 1. The MMA 10 comprises an imaging array 9 comprising a plurality of individual imaging elements 12. Each imaging element 12 may comprise a number of optical sub-elements, such as the sub-elements 14, 16, 18 and 20. In this example, the sub-elements 14, 16 and 18 are lenses and the sub-element 20 is an imaging device, such as a CMOS array. More or fewer optical sub-elements may be employed in the imaging elements. The optical sub-elements are typically mounted on a support 22 so that each imaging element 12 defines an optical imaging axis OA₁₂ for that imaging element.

According to the standard image processing methods discussed above, the MMA 10 would typically be provided with a detector interface 24 for connecting the microscope to a data acquisition board (“DAQ”) 25 which provides an interface for receiving the image data produced by the detectors 20 of the imaging elements 12. Also according to the standard image processing methods provided in the prior art, this data would typically be streamed onto hard drives 27 or computer memory. A computer 26 interfaces with the DAQ to retrieve the data and process the data so that it can be usefully viewed.

An object to be viewed is placed on a stage or carriage 28 which is moved with respect to the MMA so as to be scanned by the imaging array 9. The array would typically be equipped with a linear motor 30 for moving the imaging elements axially to achieve focus.

The MMA 10 also includes an illumination system (not shown) which may be a trans-illumination or epi-illumination system.

Overview of the Description and Reference Information

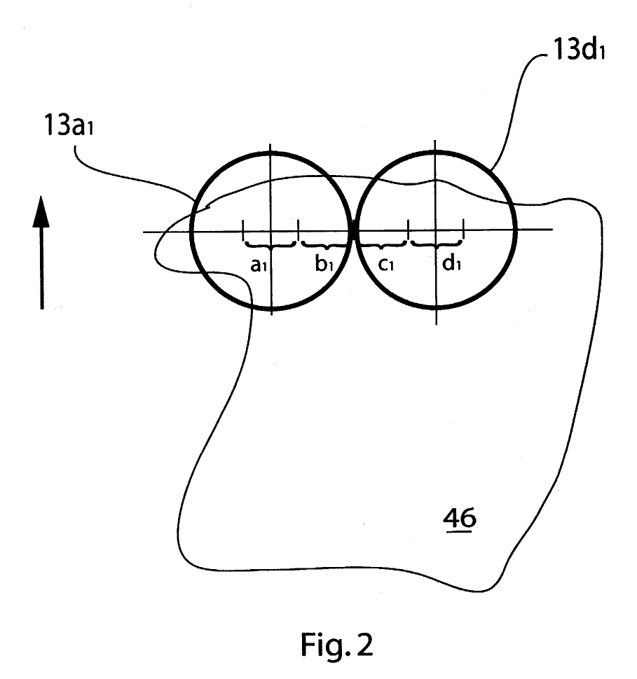

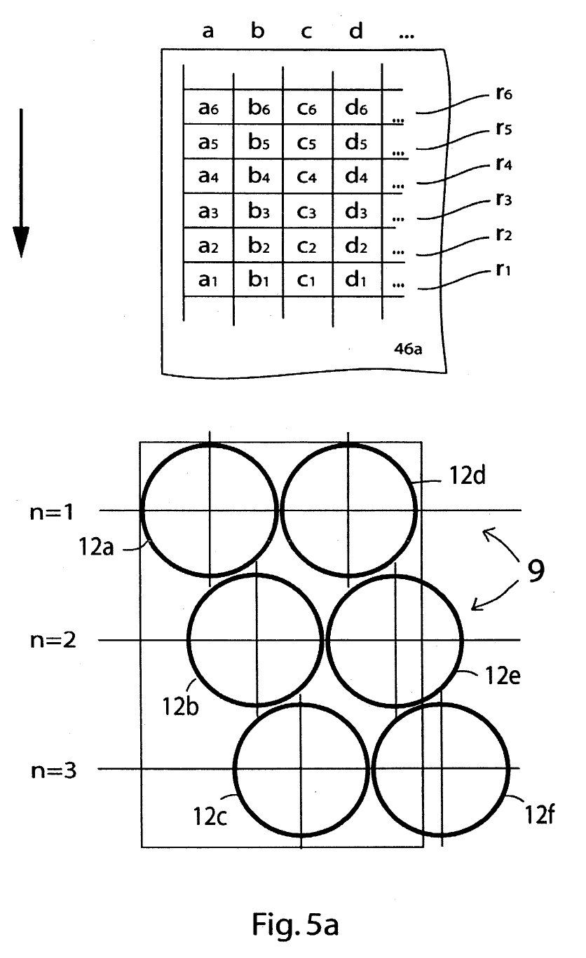

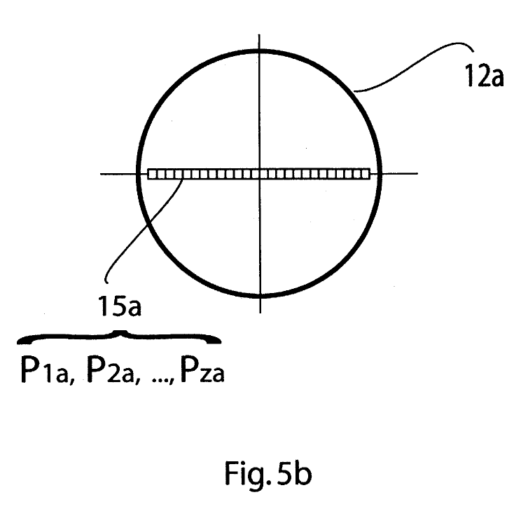

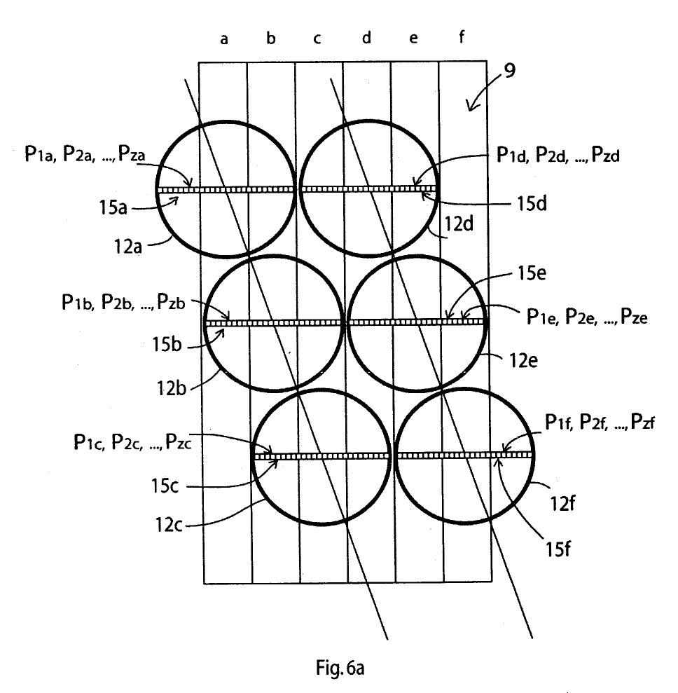

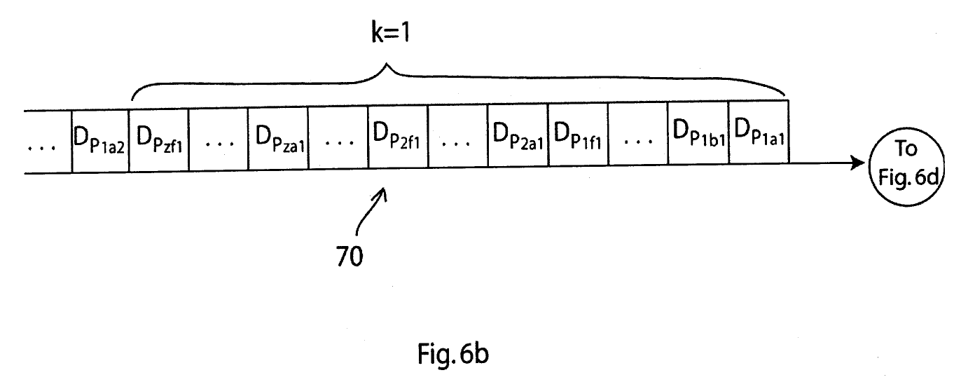

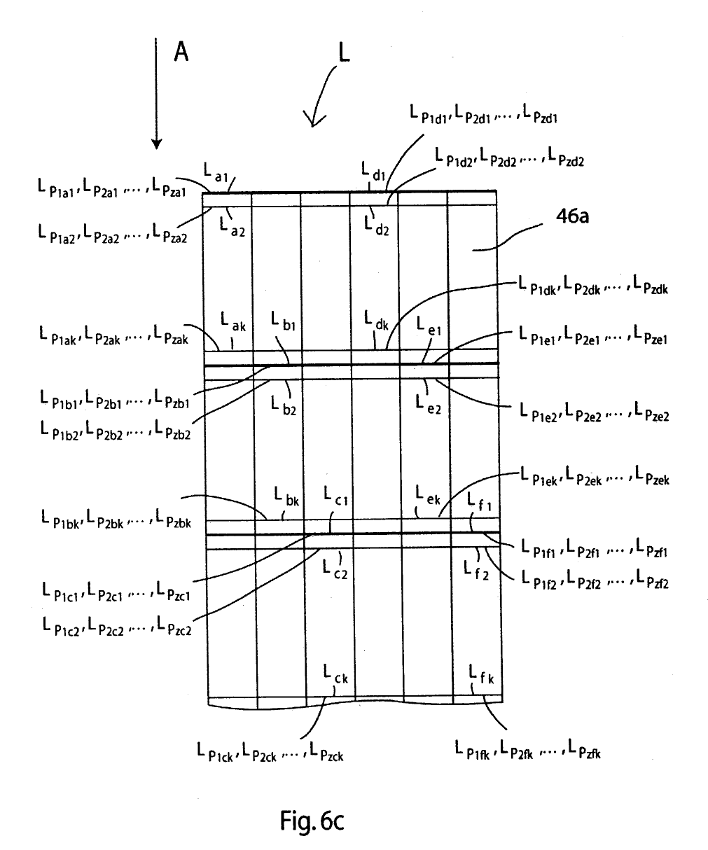

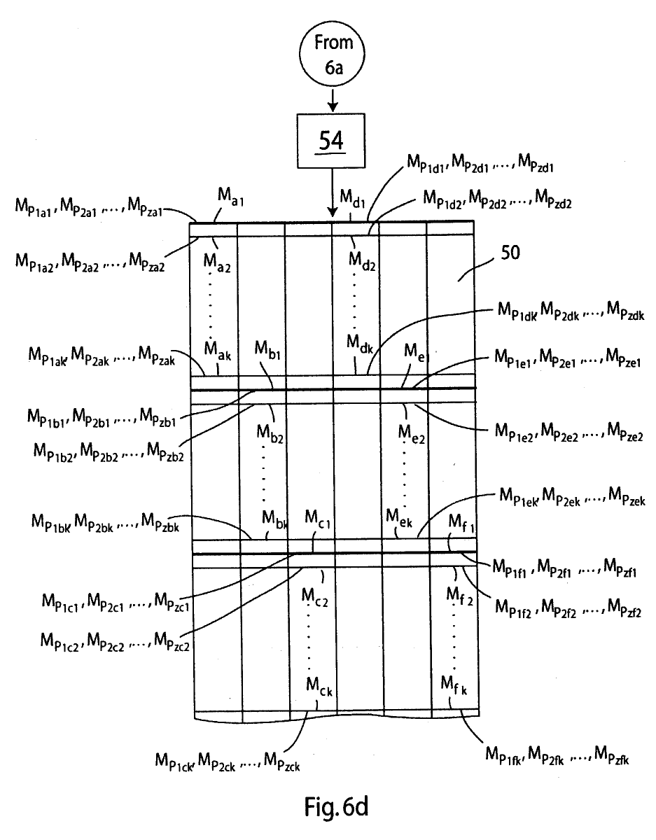

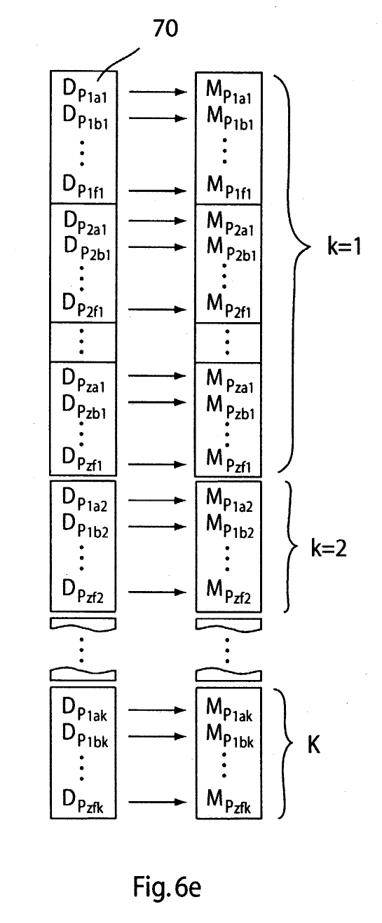

A discussion of the problem that results from the need to transfer data from the MMA, and their solutions is hereafter provided. FIGS. 2-4 illustrate that the more than one row of imaging elements is generally required to image a single row across an object to be imaged. In FIG. 5A, a six element imaging array is presented to show how the MMA scans the object. The discussion concerning FIG. 5A shows how data is acquired by the imaging array, which introduces the fundamental problem to which the invention is directed. FIGS. 5B-6E are provided for illustrating first the basic problem, and then a subsidiary problem that is similar to the basic problem but results from a different cause. A generalized imaging array is also presented along with a generalized transmitted data stream. To facilitate understanding, the following terms are referenced in that discussion with the indicated notation:

TABLE 1
Six element imaging array example

| | |
|---|---|
| Row of imaging array | n |
| Column of imaging array | m |
| Segments (on object) | a, b, c, d, e, f |
| Physical locations (of segments) | La, Lb, Lc, Ld, Le, Lf |
| Imaging elements | 12a, 12b, 12c, 12d, 12e, 12f |
| Detectors | 15a, 15b, 15c, 15d, 15e, 15f |
| Data (gross, for each detector) | Da, Db, Dc, Dd, De, Df |

Pixel detecting elements (z pixels per detector)

| | |
|---|---|
| Detector 15a: | p₁ₐ, p₂ₐ, . . . p_{za} |
| Detector 15b: | p_{1b}, p_{2b}, . . . p_{zb} |
| Detector 15c: | p_{1c}, p_{2c}, . . . p_{zc} |
| Detector 15d: | p_{1d}, p_{2d}, . . . p_{zd} |
| Detector 15e: | p₁ₑ, p₂ₑ, . . . p_{ze} |
| Detector 15f: | p_{1f}, p_{2f}, . . . p_{zf} |

Pixel data points (fine data for each pixel)

| | |
|---|---|
| Detector 15a: | Dp₁ₐ, Dp₂ₐ, . . .Dp_{za} |
| Detector 15b: | Dp_{1b}, Dp_{2b}, . . . Dp_{zb} |
| Detector 15c: | Dp_{1c}, Dp_{2c}, . . . Dp_{zc} |
| Detector 15d: | Dp_{1d}, Dp_{2d}, . . . Dp_{zd} |
| Detector 15e: | Dp₁ₑ, Dp₂ₑ, . . . Dp_{ze} |
| Detector 15f: | Dp_{1f}, Dp_{2f}, . . . Dp_{zf} |

Individual physical points (location on object corresponding to each pixel
detecting element)

| | |
|---|---|
| Detector 15a: | Lp₁ₐ, Lp₂ₐ, . . . Lp_{za} |
| Detector 15b: | Lp_{1b}, Lp_{2b}, . . . Lp_{zb} |
| Detector 15c: | Lp_{1c}, Lp_{2c}, . . . Lp_{zc} |
| Detector 15d: | Lp_{1d}, Lp_{2d}, . . . Lp_{zd} |
| Detector 15e: | Lp₁ₑ, Lp₂ₑ, . . . Lp_{ze} |
| Detector 15f: | Lp_{1f}, Lp_{2f}, . . . Lp_{zf} |

Memory locations (corresponding to physical locations of segments)

| | |
|---|---|
| Location La | Ma |
| Location Lb | Mb |
| Location Lc | Mc |
| Location Ld | Md |
| Location Le | Me |
| Location Lf | Mf |

Individual memory locations (memory locations corresponding to physical
locations on object corresponding to individual pixels)

| | |
|---|---|
| Ma | Mp₁ₐ, Mp₂ₐ, . . . Mp_{za} |
| Mb | Mp_{1b}, Mp_{2b}, . . . Mp_{zb} |
| Mc | Mp_{1c}, Mp_{2c}, . . . Mp_{zc} |
| Md | Mp_{1d}, Mp_{2d}, . . . Mp_{zd} |
| Me | Mp₁ₑ, Mp₂ₑ, . . . Mp_{ze} |
| Mf | Mp_{1f}, Mp_{2f}, . . . Mp_{zf} |

Frame index k
(k may be added as a last index to any data or memory element)

Generalized imaging array

| | |
|---|---|
| Row of imaging array | n |
| Column of imaging array | m |
| Q | m • n |
| Detectors | 1, 2, . . . Q |

Pixel detecting elements (z pixels per detector) (NOTE: first index = # of
pixel, second index = # of imaging element)

p₁₁, p₁₂, . . . p_{1Q}
p₂₁, p₂₂, . . . p_{2Q}
p_{z1}, p_{z2}, . . . p_{zQ}

Data (NOTE: first index = # of pixel, second index # of imaging element,
third index = # of frame)

Dp₁₁ₖ, Dp₁₂ₖ, . . . Dp_{1Qk}
Dp₂₁ₖ, Dp₂₂ₖ, . . . Dp_{2Qk}
Dp_{z1k}, Dp_{z2k}, . . . Dp_{zQk}

Tile (exemplary) (NOTE: first index = # of pixel, second index = # of
imaging element)

Dp₁₁, Dp₁₂, . . . Dp_{1Q}
Dp₂₁, Dp₂₂, . . . Dp_{2Q}
Dp_{z1}, Dp_{z2}, . . . DP_{zQ}

Frame index k
(k may be added as a last index to any data or memory element)

Geometry of The Basic Imaging Array in an MMA

Turning now to FIG. 2, an example of a method for acquiring data from the MMA 10 is described to show that a two-dimensional array of imaging elements is required to image a single object row “r” across an object 46 in an array microscope embodiment of the invention. In the example given, the object row “r” comprises the four equal-length linear segments a₁, b₁, c₁, and d₁. While the example illustrates a principle of data acquisition according to the present invention, it is highly simplified to facilitate understanding and does not represent a preferred embodiment of a method for data acquisition according to the present invention.

To image the linear segment a₁, a single imaging element 12a₁ shown in plan view is centered thereon as shown. The imaging element 12a₁ is larger than the segment a₁ to provide a high numerical aperture; in the example shown, the imaging elements have a diameter that is 3 times the length of the corresponding linear segment; however, this ratio may be any that is desired. Packing a second imaging element 12d₁ as closely as possible to the imaging element 12a₁ along the axis of the object row “r” permits imaging the linear segment d₁. However, the segments b₁ and c₁ cannot be imaged.

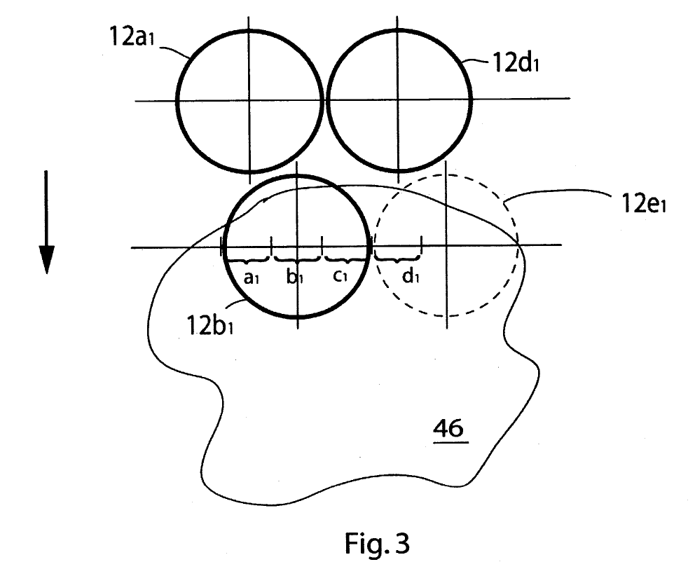

FIG. 3 shows the object 46 having been translated with respect to the imaging elements in the scan direction indicated by the arrow relative to its position in FIG. 2. This translation brings the linear segment b₁ into view of an imaging element 12b₁ centered thereon as shown; however, the linear segment c₁ still cannot be imaged.

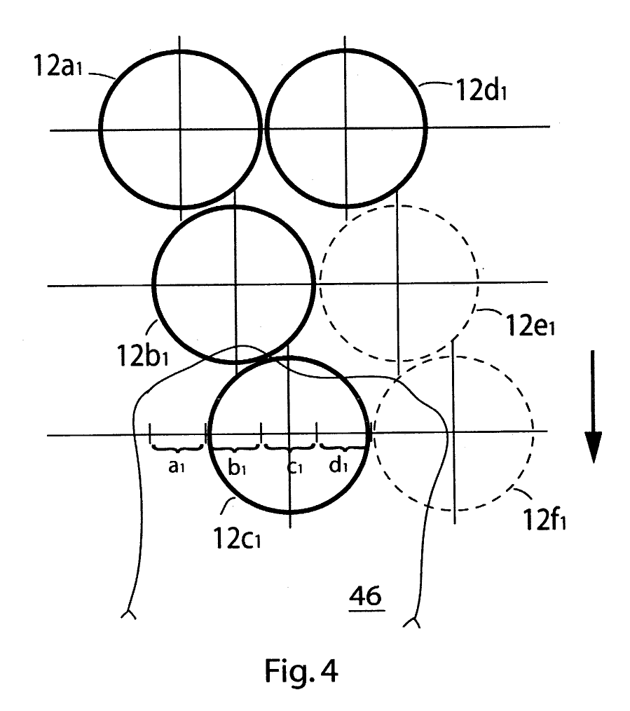

Turning to FIG. 4, the same object 46 is shown translated once again in the scan direction indicated by the arrow. This translation brings the segment c₁ into view of an imaging element 12c₁ centered thereon. It is apparent in FIG. 4 that the two-dimensional imaging array 9 defined by imaging elements 12a₁, 12b₁, 12c₁, and 12d₁ is required to image the four segments a₁, b₁, c₁, and d₁ of the object row “r.” Other imaging elements 12e₁ and 12f₁ corresponding to segments not shown are illustrated in FIG. 4 (in dotted line) to make the arrayed arrangement of the imaging elements more clear.

The imaging array 9 defined by the imaging elements 12a₁, 12b₁, 12c₁, 12d₁, 12e₁, and 12f₁ can be described as having m columns, where m=2 in this example, and n rows, where n=3 in this example. For example, the imaging elements 12a₁ and 12d₁ may be identified as forming the first row of the array, the imaging elements 12b₁ and 12e₁ may be identified as forming the second row of the array, and the imaging elements 12c₁ and 12f₁ may be identified as forming the third row of the array. Also, the imaging elements 12a₁, 12b₁, and 12c₁ may be identified as forming the first column of the array and the imaging elements 12d₁, 12e₁, and 12f₁ may be identified as forming the second column of the array.

The rows and columns of the imaging array do not need to be perpendicular to each other, so that the imaging elements of each row (or column) are staggered with respect to the imaging elements of the preceding and subsequent rows (or columns). Preferably, the rows (or columns) are perpendicular to the scanning direction but this is not necessary either, it being understood that where the rows (or columns) are not perpendicular to the scanning direction, compensating correction of the acquired geometry may be required. It should also be noted that the selection of which of two dimensions is associated with a row and which is associated with a column is completely arbitrary.

Simplified Example of Scanning with the Basic Imaging Array in an Array Microscope

Turning to FIG. 5A, the imaging array 9 of FIGS. 2-4 is shown with an object 46a having six object rows r₁, r₂, r₃, r₄, r₅, and r₆ of four linear segments each to be imaged. Like FIGS. 2-4, FIG. 5A depicts a highly simplified situation to facilitate understanding of basic principles. The linear segments define four object columns a, b, c, and d. The array 9 has n=3 rows of imaging elements 12 as shown in FIG. 4. The object 46a is moved relative to the array 9 in the scan direction indicated by the arrow.

At a time t=1, when the row r₁ across the object is aligned with the row n=1 of the array 9, the segments a₁ and d₁ are imaged as described above by the imaging elements 12a and 12d. At a next time t=2, when the row r₁ is aligned with the row n=2 of the array 9, the segment b₁ is imaged by the imaging element 12b as described above. Also at the same time t=2, the imaging elements 12a and 12d image the segments a₂ and d₂ of the next row r₂.

At a next time t=3, when the row r₁ is aligned with the row n=3 of the array 9, the segment c₁ is imaged by the imaging element 12c as described above. Also at the same time, the imaging element 12b images the segment b₂ of the row r₂, and the imaging elements 12a and 12d image the segments a₃ and d₃ of the row r_{3.}

At a next time t=4, the row r₁ has passed the array 9 and the row r₄ is aligned with the row n=1 of the array 9. At this time, segments a₄ and d₄ are imaged by the elements 12a and 12d, the segment b₃ is imaged by the element 12b, and the segment c₂ is imaged by the element 12c.

It can be seen by extension of the description above that the data for the six rows is obtained in the following order:

TABLE 2

| | | | | |
|---|---|---|---|---|
| t = 1: | a₁ | | | d₁ |
| t = 2: | a₂ | b₁ | | d₂ |
| t = 3: | a₃ | b₂ | c₁ | d₃ |
| t = 4: | a₄ | b₃ | c₂ | d₄ |
| t = 5: | a₅ | b₄ | c₃ | d₅ |
| t = 6: | a₆ | b₅ | c₄ | d₆ |
| t = 7: | | b₆ | c₅ | |
| t = 8: | | | c₆ | |

Scanning with the Basic Imaging Array at High Resolution

In practice, preferably, the optical resolution of the imaging elements 12 is about 0.5 microns. The desired scan width is achieved by providing a sufficient number of rows in the imaging array. Due to the size of the imaging elements, the rows of elements must be spaced apart essentially the same distances as the columns. To achieve a resolution of 0.5 microns, the optical elements would typically have a diameter and spacing of about 15 mm. Therefore the area of imaging elements must also be spaced about 15 mm apart, so as to obtain the same resolution in the scanning direction as along the row. This requires on the order of 3000 “frames” or row images to be taken between the rows n=1 and n=2 of the array 9 described above. With 3000 additional object rows between each two rows of the array 9, spaced Δ units apart, and where the scanning velocity is assumed to be “v”, the image data in Table 2 for the same 8 units of time would be supplemented as shown below:

TABLE 3

| | | | | | |
|---|---|---|---|---|---|
| t = 1: | | a₁ | | | d₁ |
| | t = 1 + Δ/v: | a_{1+Δ} | | | d_{1+Δ} |
| | . . . . | . . . . | | | . . . . |
| | t = 1 + 3000Δ/v: | a_{1+3000Δ} | | | d_{1+3000Δ} |
| t = 2: | | a₂ | b₁ | | d₂ |
| | t = 2 + Δ/v: | a_{2+Δ} | b_{1+Δ} | | d_{2+Δ} |
| | . . . . | . . . . | . . . . | | . . . . |
| | t = 2 + 3000Δ/v: | a_{2+3000Δ} | b_{1+3000Δ} | | d_{2+3000Δ} |
| t = 3: | | a₃ | b₂ | c₁ | d₃ |
| | t = 3 + Δ/v: | a_{3+Δ} | b_{2+Δ} | c_{1+Δ} | d_{3+Δ} |
| | . . . . | . . . . | . . . . | . . . . | . . . . |
| | t = 3 + 3000Δ/v: | a_{3+3000Δ} | b_{2+3000Δ} | c_{1+3000Δ} | d_{3+3000Δ} |
| t = 4: | | a₄ | b₃ | c₂ | d₄ |
| | t = 4 + Δ/v: | a_{4+Δ} | b_{3+Δ} | c_{2+Δ} | d_{4+Δ} |
| | . . . . | . . . . | . . . . | . . . . | . . . . |
| | t = 4 + 3000Δ/v: | a_{4+3000Δ} | b_{3+3000Δ} | c_{2+3000Δ} | d_{4+3000Δ} |
| t = 5: | | a₅ | b₄ | c₃ | d₅ |
| | t = 5 + Δ/v: | a_{5+Δ} | b_{4+Δ} | c_{3+Δ} | d_{5+Δ} |
| | . . . . | . . . . | . . . . | . . . . | . . . . |
| | t = 5 + 3000Δ/v: | a_{5+3000Δ} | b_{4+3000Δ} | c_{3+3000Δ} | d_{5+3000Δ} |
| t = 6: | | a₆ | _{b5} | c₄ | d₆ |
| | t = 6 + A/v: | a_{6+Δ} | b_{5+Δ} | c_{4+Δ} | d_{6+Δ} |
| | | . . . . | . . . . | . . . . | . . . . |
| | t = 6 + 3000Δ/v: | a_{6+3000Δ} | b_{5+3000Δ} | c_{4+3000Δ} | d_{6+3000Δ} |
| t = 7: | | | b₆ | c₅ | |
| | t = 7 + Δ/v: | | b_{6+Δ} | c_{5+Δ} | |
| | . . . . | | . . . . | . . . . | |
| | t = 7 + 3000Δ/v: | | b_{6+3000Δ} | c_{5+3000Δ} | |
| t = 8: | | | | c₆ | |
| | t = 8 + Δ/v: | | | c_{6+Δ} | |
| | . . . . | | | . . . . | |
| | t = 8 + 3000Δ/v: | | | c_{6+3000Δ} | |

The Fundamental Problem

As for Table 2, each column in Table 3 represents a contiguous strip of such data, where the different times represent “frames” of the data. It is apparent from both Tables 2 and 3 that data corresponding to contiguous segments of the object are not contiguous in time. Therefore, if the data are captured in the order they are generated, they must be reorganized to form an image. Put more generally, the data generated in object space of the imaging elements must be reordered to match the corresponding regions in image space determined by the spatial relationship of the imaging element. As can be seen by the examples provided, this problem is inherent in the geometry of the MMA. Reorganization can be done after storing all of the data representing the object until after scanning is complete; however, this method inherently lengthens the time between when the data are acquired and when the data may be displayed. As explained above, this is highly undesirable, especially in the context of the MMA.

A Secondary Problem

A secondary problem that is similar in nature to the afore-described fundamental problem arises due to the nature of the types of devices used for imaging. Referring to FIG. 5B, an exemplary one of the imaging elements 12a is shown along with a corresponding linear detector array 15a. The detector 15a includes a number of pixel detecting elements p₁ₐ, p₂ₐ, p₃ₐ, p_{za}. Each pixel detecting element collects optical information at the resolution of the MMA. More particularly, all of the pixel detecting elements p_{za}, . . . p_{zf} are preferably provided as a single two-dimensional array. To read image data from such an array as embodied in current technology, acquired image data is transferred row-by-row (or column-by-column) through a single row (or column). As other photo detector technologies may be developed making available different orders of data output, it should be understood that any such technology may be used in the present invention, so that the data output order may vary in any predetermined manner from what is described herein.

Turning to FIG. 6A, the imaging array 9 of FIG. 5A is shown with corresponding detectors 15. Considering the detectors 15 to form a two-dimensional array, data is typically read out from the pixel detecting elements “p” in the following order: p₁ₐ, p_{1b}, p_{1c}, p₂ₐ, p_{2b}, p_{2c}, . . . p_{za}, p_{zb}, p_{zc}, p_{1d}, p₁ₑ, p_{1f}, p_{2d}, p₂ₑ, p_{2f}, . . . p_{zd}, p_{ze}, p_{zf}, for the example of row-by-row transfer in the two-dimensional array.

As can therefore be seen, due to the currently available technologies, the data from individual pixels within this detector array of an imaging element are read out of adjacent detector arrays in interlaced fashion. More specifically, in the preferred embodiment data from corresponding pixel detecting elements in one column are read out consecutively, and each such column of data is read out consecutively, so that the data from pixel detecting elements of different detector arrays are interlaced in a serial data stream.

Therefore, just as in the fundamental problem, where data taken from the respective imaging elements as a whole is streamed (see again Tables 2 and 3) so that data corresponding to contiguous segments of the object are not contiguous in time, the same type of problem exists as a result of the transmission of data from the detectors 15. Particularly, for each segment, data is streamed from the detectors 15 so that data corresponding to pixels of the segment that are contiguous in time are not contiguous in space. Therefore, for this additional reason as well, if the data are streamed in the order they are received, they must be reorganized for viewing.

Microscope Array

As mentioned above, the examples provided pertain to an array microscope embodiment of the MMA 10. However, a similar data-scrambling problem exists for a microscope array. Particularly, regardless of the order in which the image data is read from the imaging array during a single frame, there will in general be image data acquired by the imaging elements for one frame that must be interlaced with image data acquired by the same imaging elements in the next frame. Fundamentally, the data scrambling problem exists whenever an imaging array outputs image data in an order that differs from the order in which the data were acquired.

Memory Mapping Solution

To solve the aforementioned problems according to a first, memory mapping aspect of the invention, data are streamed from the imaging elements in the disorganized order in which they are acquired. While disorganized in the sense that the data are not necessarily in an order that facilitates viewing, the order of the data is predetermined by the manner the data are streamed, such as described above in connection with FIG. 6A. Any other predetermined order may be chosen.

Referring to FIGS. 6A-6E, image data from the imaging array 9 shown in FIG. 5A is streamed from the array. The imaging array comprises imaging elements 12a, 12b, 12c, 12d, 12e and 12f, along with their corresponding detectors 15a, 15b, 15c, 15d, 15e and 15_{f} such as shown in FIG. 5B. The detector 15a includes corresponding pixel detecting elements (not shown) p₁ₐ, p₂ₐ, p₃ₐ, p_{za}, the detector 15b includes corresponding pixel detecting elements p_{1b}, p_{2b}, p_{3b}, . . . p_{zb}, and so on, arrayed as shown in FIG. 5B.

The imaging elements image respective segments aₖ, bₖ, cₖ, dₖ, eₖ, and fₖ, of an object (or objects) 46a (FIG. 5A), where k represents frames corresponding to unit relative movements of the imaging array 9 with respect to the object. Relative movement between the imaging array 9 and the object is typically at a constant velocity; however, this is not essential to the invention.

The imaging array 9 is moved relative to the object 46a in the direction of the arrow “A” shown in FIG. 6C to obtain image data D output as shown in FIG. 6B. The image data D correspond to the imaging elements 12a-f; particularly Daₖ, Dbₖ, Dcₖ, Ddₖ, Deₖ, and Dfₖ, which in turn correspond to the physical locations Laₖ, Lbₖ, Lcₖ, Ldₖ, Leₖ, and Lfₖ, respectively, generally referred to herein as “L.” More particularly, each datum D for a given imaging element 12 includes individual pixel data points corresponding to each of the pixel detecting elements of the detector of the imaging element. Accordingly, the datum Daₖincludes individual pixel data points Dp₁ₐₖ, Dp₂ₐₖ, . . . , Dp_{zak}, the datum Dbₖ includes individual pixel data points Dp_{1bk}, Dp_{2bk}, . . . , Dp_{zbk}, and so on. Generally, data acquired at the same time do not correspond to physically adjacent locations on the object 46a, because the corresponding imaging elements are disposed in different rows “n” of the imaging array.

Turning to FIG. 6B, the data may be output as a data stream 70, in the order shown, or in any predetermined order. Generally, however, the order is sequential.

FIG. 6C indicates the physical locations L of the segments Laₖ, Lbₖ, Lcₖ, Ldₖ, Leₖ, and Lfₖ on the object 46a. More particularly, each physical location L for a given segment includes individual physical points corresponding to each of the pixel detecting elements of the detector of the corresponding imaging element. Accordingly, the physical location Laₖ includes individual physical points Lp₁ₐₖ, Lp₂ₐₖ, . . . , Lp_{zak}, the physical location Lbₖ includes individual physical points Lp_{1bk}, Lp_{2bk}, . . . , Lp_{zbk}, and so on.

Now turning to FIG. 6D, a random access memory 50 is provided for storing the image data D. The memory 50 is provided with corresponding memory locations M, particularly Maₖ, Mbₖ, Mcₖ, Mdₖ, Meₖ, and Mfₖ. More particularly, each memory location M for a given segment a, b, c, d, e and f includes individual memory locations corresponding to each of the individual pixel data points. Accordingly, the memory location Maₖ includes individual memory locations Mp₁ₐₖ, Mp₂ₐₖ, Mp_{zak}, the memory location Mbₖ includes individual memory locations Mp_{1bk}, Mp_{2bk}, . . . , Mp_{zbk}, and so on. The memory 50 would in practice have a much larger memory capacity for storing data preferably providing a 0.5 micron resolution over a 20 mm×50 mm microscopy slide.

According to the memory mapping aspect of invention, the memory locations “M” of the memory 50, particularly the individual memory locations thereof, are organized to correspond physically with the physical locations “L,” particularly the individual physical points thereof, meaning that data in “adjacent” memory locations correspond to adjacent fields of view of the object. For purposes herein, “adjacent” memory locations are locations in memory that may be addressed consecutively. Typically, the memory locations are physically adjacent one another in the memory as well, so that simply reading (or writing to) a row or a column from the memory automatically addresses the adjacent memory locations consecutively, however, the memory be otherwise organized so that memory locations may be physically separated from one another while retaining the ability to provide consecutively ordered outputs.

A signal processor 54, such as a digital signal processor (“DSP”), field programmable gate array (“FPGA”), programmable logic array (“PLA”) or other suitable electronic device is programmed to anticipate the order in which data will be received, and to reorganize the data by storing the data associated with particular physical locations aₖ, bₖ, cₖ, dₖ, eₖ, and fₖ on the object into the corresponding memory locations Maₖ, Mbₖ, Mcₖ, Mdₖ, Meₖ, Mfₖ. More particularly, the signal processor 54 preferably stores the data associated with individual points Lp₁ₐ₁, Lp_{1b1}, . . . , Lp_{1f1}, Lp₂ₐ₁, Lp_{2b1}, . . . , Lp_{2f1}, . . . Lp_{za1}, Lp_{zb1}, . . . Lp_{zf1}, respectively, in a first frame k=1 into the corresponding individual memory locations Mp₁ₐ₁, Mp_{1b1}, . . . , Mp_{1f1}, Mp₂ₐ₁, Mp_{2b1}, . . . , Mp_{2f1}, . . . Mp_{za1}, Mp_{zb1}, . . . Mp_{zf1}. Similarly, the signal processor 54 stores the data associated with individual points Lp₁ₐ₂, Lp_{1b2}, . . . , Lp_{1f2}, Lp₂ₐ₂, Lp_{2b2}, . . . , Lp_{2f2}, . . . Lp_{za2}, Lp_{zb2}, . . . Lp_{zf2}, respectively, in a second frame k=2 into the corresponding individual memory locations Mp₁ₐ₂, Mp_{1b2}, . . . , Mp_{1f2}, Mp₂ₐ₂, Mp_{2b2}, . . . , Mp_{2f2}, . . . Mp_{za2}, Mp_{zb2}, . . . Mp_{zf2}, and so on.

FIG. 6E shows the data stream 70 corresponding to this example mapped into a memory 50 by the signal processor 54. While a complete memory mapping is indicated in this example, memory mapping according to the present invention may be carried out only partially to any desired extent.

Data in the memory 50 shown in FIG. 6D corresponds physically to the locations on the object 46a from whence the data came. Accordingly, if the data are output from the memory 50 in any order in which adjacent memory locations are read sequentially, the data may be displayed in the order received to produce a viewable image. For example, the data may be read row-by-row (or column-by-column), where, within each row, the data are read column-by-column (or row-by-row), producing a simple raster scan output that facilitates display. The memory 50 is electronically addressable to provide for fast storage and retrieval.

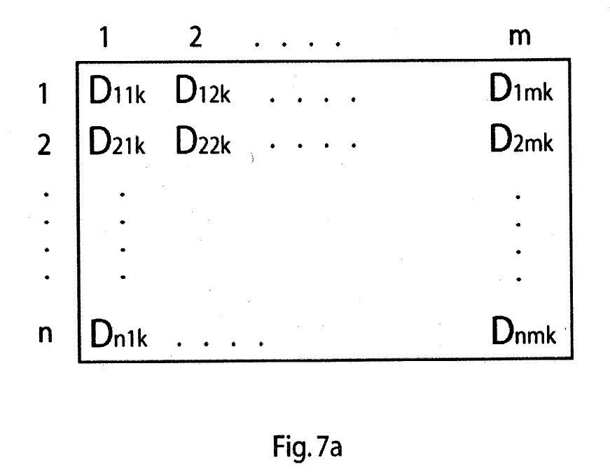

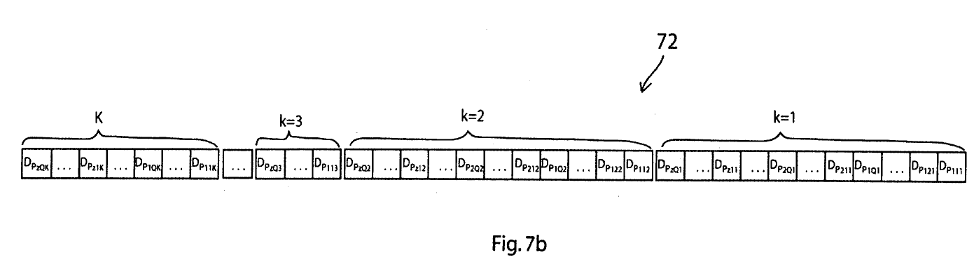

A more general example of data flow produced by the imaging array 9 is illustrated in FIG. 7B, that arises from an imaging array 9 producing a matrix of imaging data as shown in FIG. 7A. Where there were n=3 rows of m=2 imaging elements per row in FIG. 6A, all six of the imaging elements were needed to image just one row across the object 46a.

Generally, the m·n matrix provides a sufficient number of rows “n” such that more than one row across the object may be imaged at one time, to provide the advantage of increasing scanning throughput. Again, the subscript “k” references the data corresponding to a particular frame. The individual pixel data points described above are omitted for clarity.

Referring to FIG. 7A, the imaging array 9 (FIG. 1) outputs “k” frames of imaging data “Dₙₘₖ” In turn, each imaging datum Dₙₘₖ includes individual pixel data points Dₚ that are interlaced with the individual pixel data points for the other imaging data as explained previously, all of which are omitted in FIG. 7A for clarity. However, FIG. 7B shows a data stream 71 that includes the individual pixel data points for each imaging datum, where Q=m·n=the total number of imaging elements 12. The data are preferably streamed in the order shown in FIG. 7B; however, the data may be streamed in any predetermined order. Generally, however, the order is sequential.

Aligning Solution

To solve the aforementioned problems according to a second, aligning aspect of the invention, the data are reorganized by aligning the columns of data in time.

Solving the Fundamental Problem

To provide a simplified example of the concept, referring back to the simplified model given in Table 2 and assuming that the data corresponding to the imaging element 12c is taken immediately, the data corresponding to the imaging element 12b is delayed one unit of time (from t=1 to t=2), and the data corresponding to the imaging elements 12a and 12d is delayed two units of time (from t=1 to t=3) to align the data in all the columns. The result of this alignment is shown below:

TABLE 4

| | | | | |
|---|---|---|---|---|
| t = 1: | | | | |
| t = 2: | | | | |
| t = 3: | a₁ | b₁ | c₁ | d₁ |
| t = 4: | a₂ | b₂ | c₂ | d₂ |
| t = 5: | a₃ | b₃ | c₃ | d₃ |
| t = 6: | a₄ | b₄ | c₄ | d₄ |
| t = 7: | a₅ | b₅ | c₅ | d₅ |
| t = 8: | a₆ | b₆ | c₆ | d₆ |

The column strips of data a, b, c, and d are now aligned with each other, so that all the image data corresponding to a single object row is made available at the same time. The alignment requires in this example storing two frames of image data corresponding to t=1 and t=2. For the data in Table 3, the alignment similarly requires storing 6000 frames of image data corresponding to t=1 through t=2+3000Δ/v. Although the particular delays obtained in Tables 2 and 3 are specific to the example given, it is recognized to be generally the case that object image data can be aligned as in Table 4 by delaying different column strips of data by appropriate amounts.

The number of frames that are stored for this alignment can be determined from the example given to be generally equal to the number of rows of the imaging array minus one. In general, if the size of the imaging elements is “n” times the size of their fields of view, the imaging array may have as few as “n” rows of imaging elements, so the number of frames stored for alignment may be as small as n−1. A much smaller memory space is therefore required according to the present invention than would be required to store all of the data corresponding to scanning the entire image. This makes it feasible to use more expensive, faster memory to save imaging time.

Data still must be streamed from the imaging array and organized for viewing. It may be noted, however, that the afore-described alignment also reorganized the data as well. According to a preferred embodiment of the invention then, the data may simply be read serially to preserve the order of adjacent column segments a, b, c, and d. For example, data from the frame t=3 in Table 4 may be read in the order a₁, b₁, c₁, and d₁ (or the reverse), and data from the frame t=4 may follow in the order a₂, b₂, c₂, and d₂ (or the reverse). This produces a simple raster scan output that facilitates display.

Solving the Secondary Problem—Generalized Imaging Array

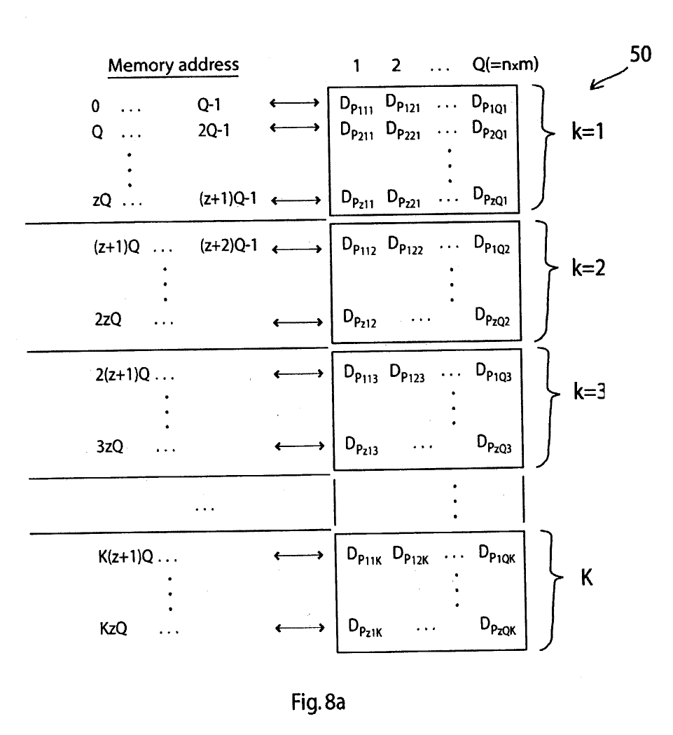

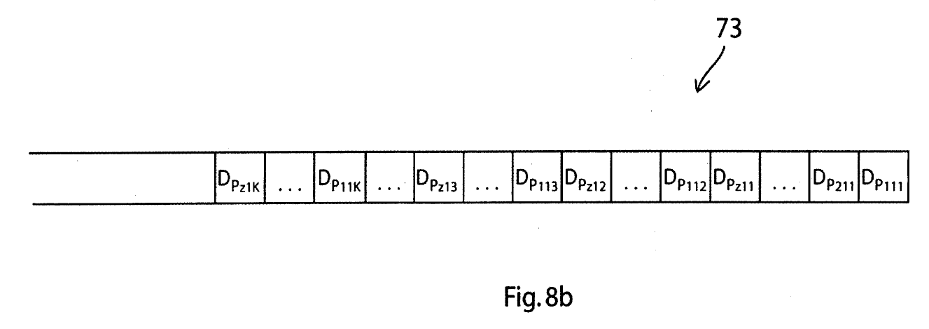

As mentioned previously, the pixel data is streamed from a two-dimensional imaging array in a particular order. Image data for each frame “k” may be read from the array by a processor, such as a DSP, FPGA, or PLA, which may buffer the data in a memory 50 as shown in FIG. 8A. The data in FIG. 8A comprises the generalized data stream 72 of FIG. 7B, showing individual pixel data points for the multiple frames “k.”

Referring back to FIG. 6A, it may be noted that each pixel detecting element p for each imaging element 12 produces a contiguous strip of individual pixel data points as the object 46a is being scanned. For example, the pixel detecting element p₁₁ (the first element of the first detector), which corresponds to the pixel detecting element p₁ₐ in FIG. 6A, produces the data circled in FIG. 8A for each frame “k.” This tile of data is referred to herein as Dp₁₁ dropping the index for “k,” so that the tile corresponds to evolution of the output of the pixel detecting element p₁₁ over the entirety of “k” frames. FIG. 8B shows the tile Dp₁ presented as a data stream 73.

Such strip is aligned precisely along the scanning direction as described above in the simplified example of Tables 1 and 3. With reference to FIG. 6A, the tile Dp₁₁ (from the first pixel detecting element of the first imaging element) corresponds to data from the pixel detecting element p₁ₐ, the strips Dp₁₂ (from the first pixel detecting element of the second imaging element) corresponds to data from the pixel detecting element p_{1b}, the strips Dp₁₃ (from the first pixel detecting element of the third imaging element) corresponds to data from the pixel detecting element p_{1c}, and so on, until reaching the strips Dp₁₆, which corresponds to data from the pixel detecting element p_{1f}.

The strip Dp₁₂ (Dp_{1b} in FIG. 6A) is aligned with the strip Dp₁₁ (Dpₗₐ in FIG. 6A), and the strip Dp₁₃ (Dp_{1c} in FIG. 6A) is aligned with the strip Dp₁₁ and Dp₁₂ as described above. However, since there are only n=3 rows of imaging elements in FIG. 6A, the tile Dp₁₄ (Dp_{ld} in FIG. 6A) is already aligned with the tile Dp₁₁, because it is on the same row. Similarly, the tile Dp₁₅ (Dp₁ₑ in FIG. 6A) is already aligned with the tile Dp₁₂, and the tile Dp₁₆ (Dp_{1f} in FIG. 6A) is already aligned with the tile Dp₁₃. Accordingly, the “Q” columns in FIG. 8A are grouped, for alignment purposes, in “m” blocks of “n” columns. Generally, for data ordered as provided above, there are “m” blocks of “n” columns Q, wherein alignment is carried out within each block by delaying the column (Q+j) by “j” frames “k,” where j ranges from 1 to “n.”

Methods for aligning data provided in some other order may be determined using the same principles illustrated by the present example. The tiles may be aligned “on the fly,” or stored for subsequent alignment such as in the memory 50.

The strips, or columnar strips of data, correspond to columnarly contiguous physical locations on the object being scanned. However, alternative strips of data according to the present invention may be taken from the memory 50 or obtained “on the fly” with or without storing the data in the memory 50. The strips preferably tile the object 46a, but adjacent strips may correspond to locations on the object 46a that are not contiguous without departing from the principles of the invention.

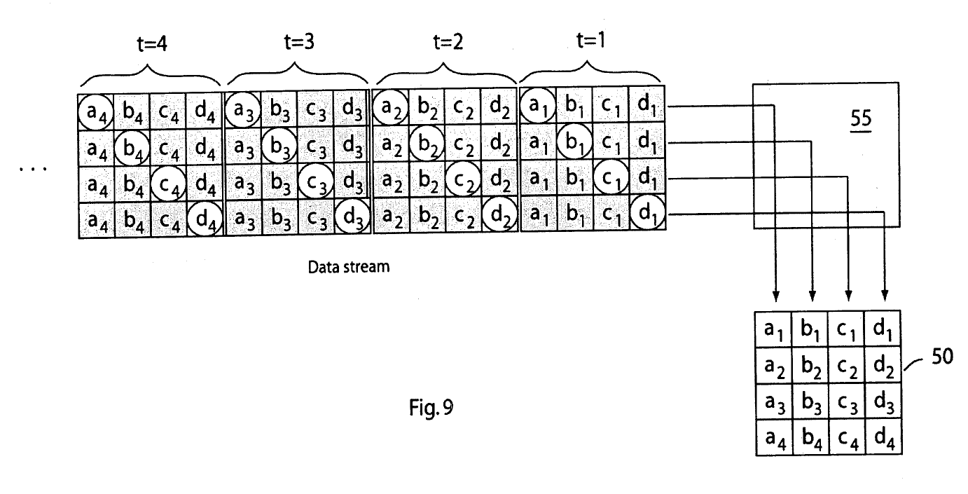

Turning to FIG. 9, alignment may be carried out alternatively by buffering the data of Table 2 and streaming the data multiple times as shown to a processor 55, such as a DSP, FPGA, or PLA. The data a, b, c, and d of Table 2, corresponding to a selected row or line of the corresponding imaging elements 12a, 12b, 12c and 12d, is selected by the processor 55 for further streaming to a display device.

In a similar manner to that described above for the memory mapping aspect of the invention, the reorganized data may in addition or in the alternative be stored in a memory 50 as it is produced so that data in adjacent memory locations in the memory correspond to adjacent fields of view of the object. Moreover, at least some of the advantages provided by the present invention may be obtained by providing a separate step of reorganization in combination with a partial or incomplete step of alignment.

Basic System Hardware

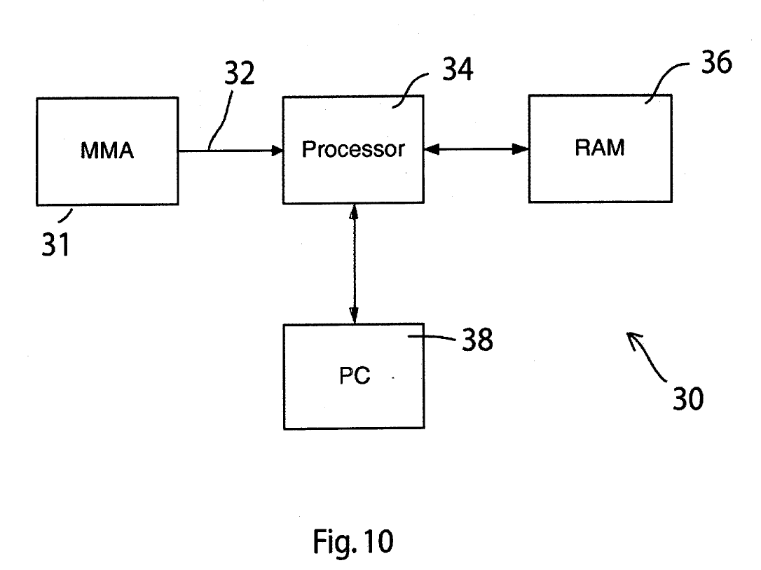

Turning to FIG. 10, a block diagram of system hardware 30 for transmitting image data from an MMA 31 according to the present invention is shown. The microscope 31 transmits image data via a high speed link 32 such as may be controlled by software marketed under the trademark CAMERALINK by Umax Data Systems, Inc. of Taiwan to a high speed processor 34, such as a DSP or PLA. The processor processes the image data such as described above to reorganize the data in a form that facilitates viewing and stores the reorganized data in a high speed random access memory (“RAM”) 36 such as dynamic semiconductor memory. The RAM 36 may also be used by the processor to store frames for alignment, or this may be done in a separate cache memory onboard the processor. A host computer 38, which may be a PC interacting with the processor through an interface such as a USB, may be provided as a display device. Alternatively, the processor may be used to drive a display device directly. While a digital signal processor coupled to high speed RAM is preferred for the purpose described, any signal processing circuit, device or system may be employed with any memory storage element or device without departing from the principles of the invention.

Alternative Basic System Hardware

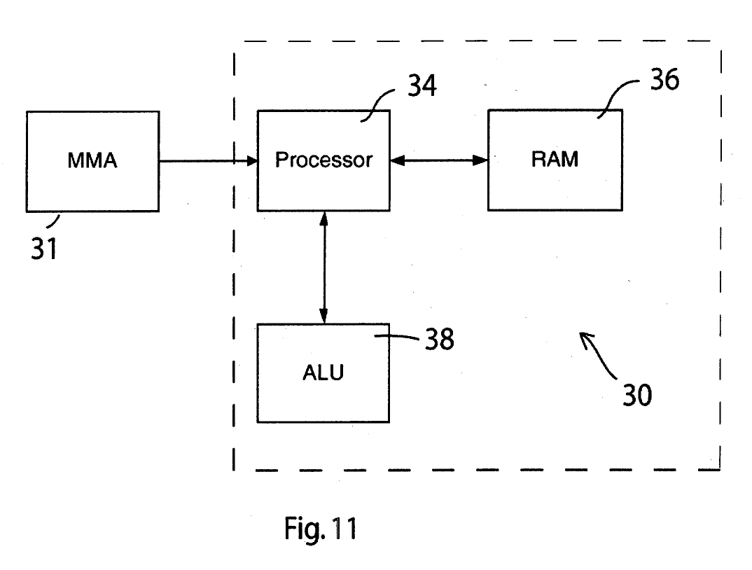

Turning to FIG. 11, an alternative embodiment 33 to the system 30 described above employs a processor 34 that is internal to the host computer 38. The processor in this embodiment communicates via an internal bus to the ALU of the computer, such as through a Peripheral Component Interconnect (PCI). The memory 36 is preferably also onboard the computer as shown, but it may be provided as a peripheral device if desired.

As mentioned above in connection with FIG. 1, each imaging element 12 includes a linear array of detectors. The data output from the detectors must typically be corrected for deviations in such performance parameters as gain and offset. The high speed processor 34 is able to provide, in addition to the capability to align the data as required or desired, the capability to perform such corrections as well.

Returning to the discussion regarding transmission of the data of Table 3, data corresponding to a number of frames may also be read out in parallel. For example, data from the frame t=3 in Table 2 may be read out as described above to one processor at the same time that data from the frame t=4 is read out to another, parallel processor.

Parallel Processing

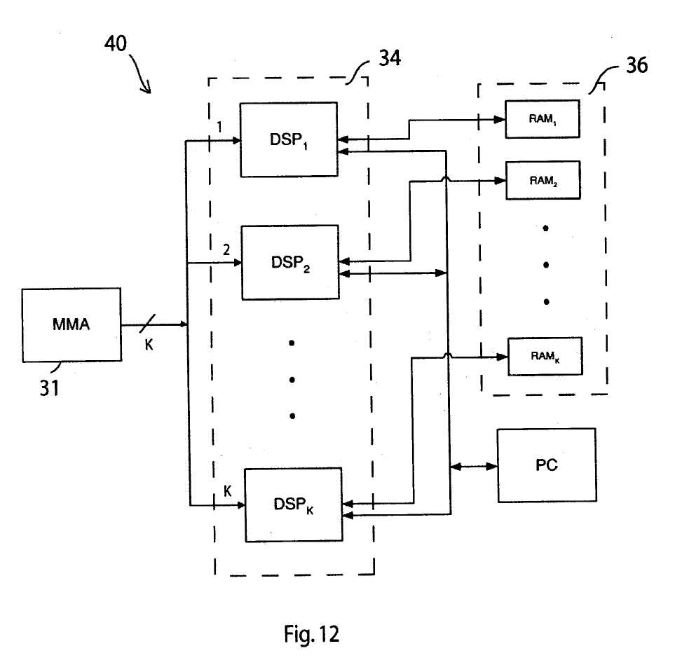

Turning to FIG. 12 a block diagram of a parallel processing system 40 for transmitting image data from the MMA 31 according to this aspect of the present invention is shown. The processor 34 and RAM 36 elements of FIG. 12 are provided as a plurality of parallel portions. Particularly, the processor 34 comprises the parallel processor portions DSP₁, DSP₂, . . . DSPₖ, to receive and process, respectively row data 1, 2, . . . k transmitted from the microscope 31 in parallel. Similarly, the RAM 36 comprises the parallel memory portions RAM₁, RAM₂, . . . RAMₖ, to store the data reorganized by the respective processor portions. Image data transmitted from the microscope 31 may be distributed to the parallel processor portions according to any desired alternative parallel processing scheme.

Such parallel processing provides one strategy for dividing the computational workload associated with obtaining an image among greater amounts of hardware. Each processor portion may be less capable and therefore provide decreased cost as compared to a single processor, wherein the parallelism may compensate for this reduction in individual performance to provide no loss in speed. Alternatively, parallel processing with high performance processor portions may be employed to greatly increase speed.

Data Division and Compression

As mentioned above, the present invention may provide a separate step of reorganization in combination with a partial or incomplete step of alignment. For example, according to another aspect of the invention, alignment may be carried out in a local area of the entire image, rather than the entire image itself.

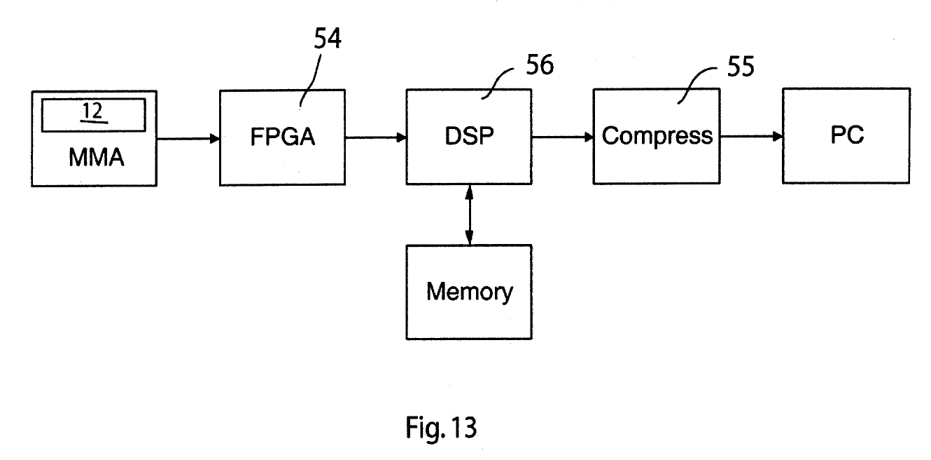

The data shown in Tables 2, 3 or 4 represent a two-dimensional array of data. The data-rate of the data streaming from the imaging elements may be reduced by grouping this data into two-dimensional tiles. Referring to FIG. 13, a data compressor 55, such as a JPEG hardware compressor or algorithm, or any other data compression hardware or software presently available or available in the future, may be used to compress the tiles and transmit the tiles to a host computer as blocks of data. In a preferred embodiment of the invention, a pre-processor 54, here an FPGA, buffers eight lines from each row of imaging elements 12 and once this amount of data is accumulated, groups the data in 8·8 tiles, the dimensions being typically determined by the compressor.

Preferably, a post-processor 56, here a DSP, aligns the data within each tile according to the aforementioned alignment aspect of the invention or performs additional operations such as gain and offset correction for each pixel location on the detector. Subsequently, the tiles are input to the data compressor 55 for transmission to a host computer such as a PC. This provides an increase in the throughput of transmission of about a factor of ten.

In addition, the host computer need only align the tiles together, rather than the 64 data points within each tile, as a result of the processing provided by the processors 54 and 56, resulting in a 64-fold reduction in the host computer's work load. Accordingly, a lower speed processor may be used to align the data within a tile and send the data to another lower speed processor used to stitch together the tiles and store the stitched tiles in an onboard memory 56, so that no additional processing will be required to view the image upon retrieval of the image from the memory 56.

Where the host computer is a PC, this is a sufficient reduction to permit the PC to complete the alignment “on the fly.” As with parallel processing, digital compression according to the present invention provides a strategy for dividing the computational overhead associated with obtaining an image among a number of processors. In this example, some of the workload has been distributed to the PC, which, otherwise, would not be fully utilized.

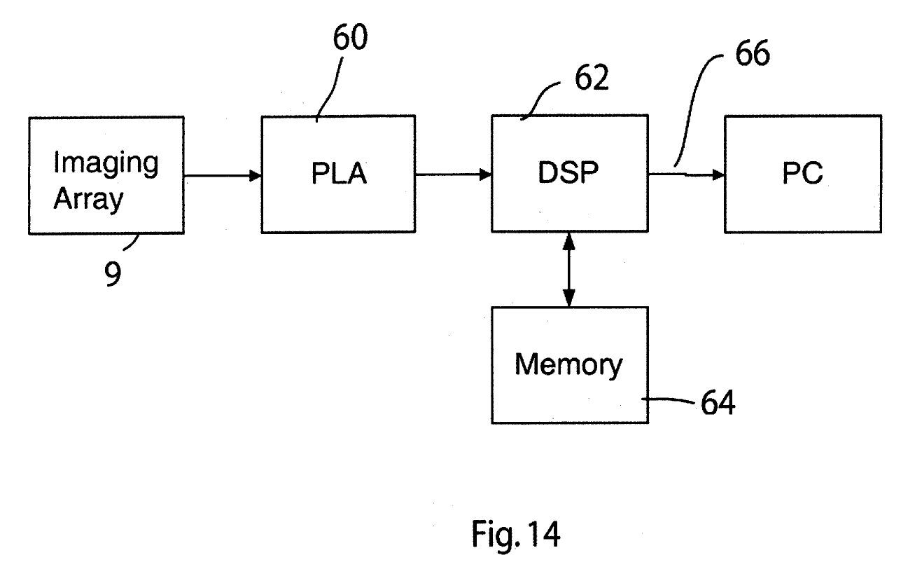

As another alternative, FIG. 14 shows a pre-processor 60, here a PLA, which pre-organizes data received from the imaging array 9, and transmits the pre-organized data to a post-processor 62, which may be a DSP, which completes reorganization of the data for viewing. In this example, the DSP is coupled to a memory 64 and provides reorganized image data to a PC through a high-speed link 66. The pre-processor may align the data to any desired partial extent while the post-processor continues to realign the data to any desired extent, storing the data in the memory and providing the data to the PC. The post-processor may fully complete the realignment, storing and providing an image that is ready for viewing to the PC, or the PC may be used as a further post-processing device.

Any of the aforementioned strategies may be used alone or in combination, to varying degrees, to optimally distribute the data processing required among the data processing circuits or systems available so that an image produced by the imaging elements may be transmitted therefrom in a form that is either ready for viewing without further processing, or that can be processed at a viewing station substantially as fast as the data is received, so that the image can be viewed in real time.

Data Correction and Compensation

In addition to the data reorganization required for viewing a stream of data output from an MMA, the MMA also preferably includes compensation for manufacturing variances in the optical axes of the imaging elements of the imaging array. In a preferred embodiment, a detector array that spans the entire width of the array of imaging elements is used, each imaging element along a row of the array of imaging elements employing a section of the detector array. Consequently, in contrast to prior art scanning systems, such as that disclosed by U.S. Pat. No. 5,144,448, there is no need to compensate for mechanical misalignment of discrete detector arrays associated with each imaging element. However, there is a need to compensate for the entirely different problem of misalignment of the optical axis of the imaging elements which can cause image offset at the detector array. Such compensation is preferably accomplished by providing an overlap in the image fields of view of the imaging elements responsible for imaging contiguous segments of the object or objects being imaged.

Along with correction for gain and offset and image geometry as mentioned above, the image data are preferably also processed to eliminate this overlap for viewing the image. Any known method may be employed for this purpose, such as calibrating the MMA for this overlap and determining the appropriate locations of detectors in the imaging elements to be assembled for viewing. For example, for correcting an overlap between the detectors of two row-adjacent (or column-adjacent) imaging elements, a starting pixel element of the detectors defining a starting point of the detector for pixel elements that are not overlapped may be determined for each of the detectors by calibration. The ending point of the detector for the non-overlapping pixel elements of each detector may be determined separately by calibration or as a predetermined number of pixels from the starting pixel. As a result of respective determinations to select, or de-select, certain pixel elements of the detectors, selection of the remaining, relevant data for ultimate viewing may be accomplished in various ways. For example, all the data may be transmitted to a host computer wherein only the selected data is processed or displayed, or the data to be disregarded may be eliminated prior to transmission, or data can be read out of the detector selectively.

While some specific embodiments of a method and apparatus for transmitting images from an MMA have been shown and described, other embodiments according with the principles of the invention may be used to the same or similar advantage. It should be understood in particular that the memory mapping aspect of the invention may be employed without employing the aligning aspect, and vice versa, and that either or both may be employed in conjunction with the additional aspects discussed above.

The terms and expressions which have been employed in the foregoing specification are used therein as terms of description and not of limitation, and there is no intention, in the use of such terms and expressions, to exclude equivalents of the features shown and described or portions thereof, it being recognized that the scope of the invention is defined and limited only by the claims that follow:

1. An apparatus for acquiring an image of one or more objects, comprising:
an imaging array having a plurality of imaging elements for producing a corresponding array of image data representing the one or more objects, the spacing of the imaging elements being greater than the fields of view thereof in at least one direction;
a data processor for receiving said image data from said array microscope and reorganizing the received image data; and
a memory coupled to said data processor for storing at least a portion of the image data.

2. The apparatus of claim 1, wherein said data processor is adapted to reorganize the image data by mapping at least some of the image data to said memory so that data in adjacent memory locations correspond to adjacent fields of view of the one or more objects.

3. The apparatus of claim 1, wherein said data processor is adapted to reorganize the image data by buffering a portion of the image data with said memory so as to align at least a portion of the image data.

4. The apparatus of claim 1, wherein said data processor is adapted to reorganize the image data by buffering a portion of the image data with said memory so as to align a portion of the image data, and by mapping said aligned portion of the image data to said memory so that data in adjacent memory locations correspond to adjacent fields of view of the one or more objects.

5. The apparatus of claim 1, wherein said data processor is adapted to retrieve image data from said memory and reorganize the retrieved image data.

6. The apparatus of claim 5, wherein said data processor is adapted to store the reorganized data back in said memory.

7. The apparatus of claim 5, wherein said data processor is adapted to transmit the reorganized data to another location.

8. The apparatus of claim 1, wherein said data processor includes a plurality of parallel signal processor portions for receiving respective portions of said image data and reorganizing the respective portions of the received image data.

9. The apparatus of claim 8, wherein said memory includes a plurality of memory portions corresponding to said plurality of data processor portions for storing the image data reorganized by the respective processor portions.

10. The apparatus of claim 1, wherein said memory is a random access memory.

11. The apparatus of claim 1, wherein said data processor includes at least one of a DSP, a PLA, and an FPGA.

12. The apparatus of claim 1, further comprising a carriage for moving the one or more objects relative to said imaging elements to provide frames of image data corresponding to different rows across the one or more objects and said imaging elements, wherein, for each of said imaging elements, said frames produce corresponding strips of said image data, and wherein said data processor is adapted to delay at least a portion of one of said strips with respect to corresponding portions of others of said strips to align said portions.

13. The apparatus of claim 12, wherein said data processor is adapted to delay at least one of said strips with respect to others of said strips to align the strips so that the image data corresponding to a given row is made available at the same time.

14. The apparatus of claim 1, further comprising a data compressor for compressing the data output from said data processor, for transmission to a host computer.

15. The apparatus of claim 1, further comprising a host computer for receiving the reorganized image data from said data processor prior to storing at least a portion of the image data in said memory.

16. The apparatus of claim 15, further comprising a data compressor for compressing the data output from said data processor, for transmission to said host computer.

17. An apparatus for acquiring an image of one or more objects, comprising:
a two-dimensional imaging array comprising a plurality of imaging elements for producing a corresponding array of image data representing the one or more objects;
a carriage for moving the one or more objects relative to said imaging elements so that consecutive rows of said imaging array image laterally adjacent portions of the one or more objects during scanning of the one or more objects; and
a data processor for receiving said image data produced by said imaging array and reorganizing the received image data.

18. The apparatus of claim 14, further comprising a memory coupled to said data processor for storing at least a portion of said image data.

19. The apparatus of claim 18, wherein said data processor includes a plurality of parallel signal processor portions for receiving respective portions of said image data and reorganizing the respective portions of the received image data, wherein said memory includes a plurality of memory portions corresponding to said plurality of signal processor portions for storing the image data reorganized by the respective processor portions.

20. The apparatus of claim 18, wherein said memory is a random access memory.

21. The apparatus of claim 18, wherein said data processor is adapted to reorganize the image data by mapping at least some of the image data to said memory so that data in adjacent memory locations correspond to adjacent fields of view of the one or more objects.

22. The apparatus of claim 18, wherein said data processor is adapted to reorganize the image data by buffering a portion of the image data with said memory so as to align at least a portion of the image data.

23. The apparatus of claim 18, wherein said data processor is adapted to reorganize the image data by buffering a portion of the image data with said memory so as to align a portion of the image data, and by mapping said aligned portion of the image data to said memory so that data in adjacent memory locations correspond to adjacent fields of view of the one or more objects.

24. The apparatus of claim 17, wherein said data processor is adapted to retrieve image data from said memory and reorganize the retrieved image data.

25. The apparatus of claim 24, wherein said data processor is adapted to store the reorganized data back in said memory.

26. The apparatus of claim 24, wherein said data processor is adapted to transmit the reorganized data to another location.

27. The apparatus of claim 17, wherein said data processor includes a plurality of parallel signal processor portions for receiving respective portions of said image data and reorganizing the respective portions of the received image data.

28. The apparatus of claim 17, wherein said data processor includes at least one of a DSP, a PLA, and an FPGA.

29. The apparatus of claim 17, wherein said carriage is adapted for moving the one or more objects relative to said imaging elements to provide frames of image data corresponding to different rows across the one or more objects and said imaging elements, wherein, for each of said imaging elements, said frames produce corresponding strips of said image data, and wherein said data processor is adapted to delay at least a portion of one of said strips with respect to corresponding portions of others of said strips to align said portions.

30. The apparatus of claim 29, wherein said data processor is adapted to delay at least one of said strips with respect to others of said strips to align the strips so that the image data corresponding to a given row is made available at the same time.

31. The apparatus of claim 17, further comprising a data compressor for compressing the data output from said data processor, for transmission to a host computer.

32. The apparatus of claim 17, further comprising a host computer for receiving the reorganized image data from said data processor prior to storing at least a portion of the image data in said memory.

33. The apparatus of claim 32, further comprising a data compressor for compressing the data output from said data processor, for transmission to said host computer.

34. An apparatus for acquiring an image of one or more objects, comprising:
an imaging array comprising a plurality of imaging elements for producing a corresponding array of images on a detector;
a detector having a plurality of light detecting elements arranged in a single detector array, distinct portions of said light detecting elements corresponding to respective imaging elements, so as to produce a corresponding array of image data representing the one or more objects;
a carriage for moving the one or more objects relative to said imaging elements; and
a data processor for receiving said image data produced by said detector as the one or more objects are moved relative to said imaging elements and reorganizing the received image data.

35. The apparatus of claim 34, wherein said detector comprises a plurality of linear arrays of detecting elements disposed parallel to one another, each said linear array substantially spanning said imaging array laterally with respect to the direction of the motion.

36. The apparatus of claim 35, wherein said data processor is adapted to receive data from a detector array ordered so that contiguous data represent non-contiguous locations on an object, and reorder said data from a detector array so that, as reordered, contiguous data represent contiguous locations on the object.

37. The apparatus of claim 36, further comprising a memory, and wherein said data processor is adapted to receive said data from said detector as it is produced, and store said data, as reordered, into said memory.

38. The apparatus of claim 36, further comprising a memory for storing said image data, and wherein said data processor is adapted to retrieve said data from said memory to reorder said data.

39. The apparatus of claim 38, wherein said data processor is adapted to store said data, as reordered back in said memory.

40. The apparatus of claim 38, wherein said data processor is adapted to transmit said data, as reorganized, to another location.

41. An apparatus for acquiring an image of one or more objects, comprising:
a two-dimensional imaging array comprising a plurality of imaging elements for producing a corresponding array of image data representing the one or more objects;
a carriage for moving the one or more objects relative to said imaging elements so that consecutive rows of said imaging array image laterally-adjacent portions of the one or more objects during scanning of the one or more objects; and
a data compressor for compressing the data output from said signal processor, for transmission to a host computer.

42. The apparatus of claim 41, further comprising a host computer, wherein said data compressor is adapted to transmit compressed image data to said host computer.

43. The apparatus of claim 42, wherein said host computer is a PC.

44. An apparatus for acquiring image data, comprising:
a plurality of imaging elements having a known, ordered spatial relationship;
a plurality of detectors corresponding respectively to said imaging elements, said imaging elements being disposed so as to produce simultaneously at respective said detectors in image space thereof respective images of regions in object space thereof;
a read out mechanism for acquiring data from said detectors in a known order different from the order of said imaging elements; and
a mapping mechanism for reordering the data acquired by said read out mechanism so as to bear a desired relationship with one or more regions in object space of the imaging elements.

45. The apparatus of claim 44, wherein contiguous sets of data acquired from said detectors represent respectively non-contiguous object space regions.

46. The apparatus of claim 4558, wherein said mapping mechanism reorders said sets of data so that contiguous sets of data correspond to contiguous object space regions.

47. The apparatus of claim 46, wherein said detectors have respective arrays of detector elements and data from spatially-adjacent detector elements is read out serially.

48. The apparatus of claim 47, wherein the data that is read out serially is reordered in consecutive sections.

49. The apparatus of claim 47, wherein the data that is reordered is stored in memory as reordered.

50. The apparatus of claim 47, wherein said imaging elements are arranged in a two-dimensional array.

51. The apparatus of claim 46, wherein a set of imaging elements is arranged in a linear array, and said detectors corresponding to said imaging elements in said linear array comprise respective portions of a linear array of detector elements.

52. The apparatus of claim 51, wherein data from spatially-adjacent detector elements is read out serially and thereafter reordered.

53. The apparatus of claim 46, wherein a set of imaging elements is arranged in a two-dimensional array, and said detectors corresponding to said imaging elements in said two-dimensional array comprise respective linear arrays of detector elements aligned in substantially the same direction.

54. The apparatus of claim 53, wherein data from spatially-adjacent detector elements is read out serially and thereafter reordered.

55. The apparatus of claim 54, wherein said mapping mechanism reorders sets of data read out serially so that contiguous sets of data correspond to contiguous object space regions.

56. The apparatus of claim 55, wherein data is stored in memory as reordered.

57. The apparatus of claim 53, wherein said linear arrays of detector elements are aligned along one dimension of said array of imaging elements, and data from detector elements that are spatially-adjacent in the other dimension of the array of imaging elements is read out serially in that other direction.

58. The apparatus of claim 57, wherein said mapping mechanism reorders sets of data read out serially so that contiguous sets of data correspond to contiguous object space regions.

59. The apparatus of claim 57, wherein data is stored in memory as reordered.

60. The apparatus of claim 57, wherein said plurality of imaging elements comprises a microscope array.

61. The apparatus of claim 57, wherein the plurality of imaging elements comprises an array microscope array.

62. The apparatus of claim 61, wherein the mapping mechanism reorders sets of data read out serially so that contiguous sets of data correspond to contiguous object space regions.

63. The apparatus of claim 61, wherein the mapping mechanism reorders sets of data read out serially so that sets of data corresponding to respective object regions imaged by respective imaging elements are arranged contiguously with one another as respective image data elements, and image data elements corresponding to contiguous object regions are arranged so as to be contiguous with one another.

64. The apparatus of claim 63, wherein data is stored in memory as reordered.

65. The apparatus of claim 63, wherein the plurality of detectors comprises a two-dimensional array, the read out mechanism comprises a circuit for acquiring data from said two-dimensional array of detectors, and said mapping mechanism comprises a data processor.

66. The apparatus of claim 44, further comprising a memory for storing reordered data.

67. A method for acquiring an image of an object, comprising the steps of:
imaging the object to produce an ordered array of image data wherein each element of the array represents a different portion of the object;
reorganizing the received image data; and
storing the image data.

68. The method of claim 67, further comprising reorganizing the image data by mapping at least some of the image data to a memory so that data in adjacent memory locations of the memory correspond to adjacent fields of view of the one or more objects.

69. The method of claim 67, further comprising reorganizing the image data by buffering a portion of the image data with a memory so as to align at least a portion of the image data.

70. The method of claim 69, further comprising mapping said aligned portion of the image data to said memory so that data in adjacent memory locations of the memory correspond to adjacent fields of view of the one or more objects.

71. The method of claim 67, wherein said reorganizing is performed by parallel processing of respective portions of said image data.

72. The method of claim 67, further comprising moving the one or more objects relative to said imaging elements to provide frames of image data corresponding to different rows across the one or more objects and said imaging elements, wherein, for each of said imaging elements, said frames produce corresponding strips of said image data, and delaying at least a portion of one of said strips with respect to corresponding portions of others of said strips to align said portions.

73 The method of claim 72, further wherein said step of delaying includes delaying at least one of said strips with respect to others of said strips to align the strips so that the image data corresponding to a given row is made available at the same time.

74. The method of claim 67, further comprising compressing the received image data for transmission to a host computer prior to said step of storing the data and subsequent to said step of reorganizing the data.

75. The method of claim 74, wherein said step of reorganizing includes grouping said image data into tiles and aligning the tiles prior to said step of compressing.

76. The method of claim 76, wherein said step of storing stores said tiles in compressed form.

77. The method of claim 76, further comprising aligning the compressed tiles prior to said step of storing.

78. A method for acquiring an image of one or more objects, comprising:
providing a two-dimensional imaging array comprising a plurality of imaging elements for producing a corresponding array of image data representing the one or more objects;
moving the one or more objects relative to said imaging elements so that consecutive rows of said imaging array image laterally adjacent portions of the one or more objects during scanning of the one or more objects;
receiving said image data from said imaging array; and
reorganizing the received image data.

79. The method of claim 78, wherein said step of reorganizing includes mapping at least some of the image data to a memory so that data in adjacent memory locations of the memory correspond to adjacent fields of view of the one or more objects.

80. The method of claim 78, wherein said step of reorganizing includes buffering a portion of the image data with said memory so as to align at least a portion of the image data.

81. The method of claim 80, wherein said step of reorganizing includes mapping said aligned portion of the image data to said memory so that data in adjacent memory locations of the memory correspond to adjacent fields of view of the one or more objects.

82. The method of claim 78, wherein said step of reorganizing is performed by parallel processing of respective portions of said image data.

83. The method of claim 78, wherein said moving the one or more objects relative to said imaging elements provides frames of image data corresponding to different rows across the one or more objects and said imaging elements, wherein, for each of said imaging elements, said frames produce corresponding strips of said image data, and the method further comprises delaying at least a portion of one of said strips with respect to corresponding portions of others of said strips to align said portions.

84. The method of claim 83, wherein said step of delaying includes delaying at least one of said strips with respect to others of said strips to align the strips so that the image data corresponding to a given row is made available at the same time.

85. The method of claim 78, further comprising compressing the received image data for transmission to a host computer prior to said step of storing the data and subsequent to said step of reorganizing the data.

86. The method of claim 85, wherein said step of reorganizing includes grouping said image data into tiles and aligning the tiles prior to said step of compressing.

87. The method of claim 86, wherein said step of storing stores said tiles in compressed form.

88. The method of claim 87, further comprising aligning the compressed tiles prior to said step of storing.

89. A method for acquiring an image of one or more objects, comprising:
providing a two-dimensional imaging array comprising a plurality of imaging elements for producing a corresponding array of image data representing the one or more objects;
moving the one or more objects relative to said imaging elements so that consecutive rows of said imaging array image laterally adjacent portions of the one or more objects during scanning of the one or more objects;
compressing the image data; and
transmitting the compressed image data to a host computer.

90. The method of claim 89, wherein said step of reorganizing includes grouping said image data into tiles and aligning the tiles prior to said step of compressing.

91. The method of claim 90, wherein said step of storing stores said tiles in compressed form.

92. The method of claim 91, further comprising aligning the compressed tiles prior to said step of storing.

93. A method for acquiring image data, comprising:
providing a plurality of imaging elements having a known, ordered spatial relationship;
providing a plurality of detectors corresponding respectively to imaging elements being disposed so as to produce simultaneously at respective images of regions in object space thereof;
acquiring data from said detectors in a known order different from the order of the imaging elements; and
reordering the data acquired by the read out mechanism so as to bear a desired relationship with one or more regions in object space of the imaging elements.

94. The method of claim 93, wherein contiguous sets of data acquired from said detectors represent respectively non-contiguous object space regions.

95. The method of claim 94, wherein said sets of data are reordered so that contiguous sets of data correspond to contiguous object space regions.

96. The method of claim 95, wherein the detectors have respective arrays of detector elements and data from spatially-adjacent detector elements is read out serially.

97. The method of claim 96, wherein the data that is read out serially is reordered in consecutive sections.

98. The method of claim 96, wherein the data that is reordered is stored in a memory as reordered.
